(19) United States
(12) Patent Application Publication
(10) Pub. No.: US 2012/0273346 A1
(43) Pub. Date: Nov. 1, 2012

(54) FLOW DIVIDER SYSTEM

(75) Inventors: CHWAN-HWA CHIANG, Shindian (TW); YI-JUN HUANG, Shenzhen City (CN); HAI-BO PAN, Shenzhen City (CN); XU LI, Shenzhen City (CN); JIA-LIN CHEN, Shenzhen City (CN)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/274,538

(22) Filed: Oct. 17, 2011

(30) Foreign Application Priority Data
Apr. 29, 2011 (CN) 201110110675.8

(51) Int. Cl. C23C 14/34

(52) U.S. Cl. 204/298.07; 204/298.11

(57) ABSTRACT

A flow divider system includes a gas box defining a chamber and an outlet gate, a shield located in the chamber and shielding the outlet gate, the shield including a main body, the main body defining a number of openings communicating the chamber with the outlet gate. The shielding can further includes a number of shield boards adjustably fixed to the main body, to adjustably shield portions of the openings.

### BACKGROUND

1. Technical Field

The exemplary disclosure generally relates to flow divider systems used in magnetron sputtering device.

2. Description of Related Art

Magnetron sputtering is a process whereby atoms are ejected from a solid target due to a bombardment of the target by energetic particles of a magnetron. It is commonly used for thin-film deposition, etching and analytical techniques. However, a typical flow divider system used in magnetron sputtering process can not be adjusted to adjust the flow to better control utilization rate of the target.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary flow divider system. Moreover, in the drawings like reference numerals designate corresponding parts throughout the several views. Wherever possible, the same reference numbers are used throughout the drawings to refer to the same or like elements of an embodiment.

FIG. 1 is a cross-section view of an exemplary embodiment of flow divider system.

FIG. 2 is a schematic view of a shield of the flow divider system of FIG. 1.

FIG. 3 is a cross-section view of the flow divider system along a line III-III of FIG. 1.

### DETAILED DESCRIPTION

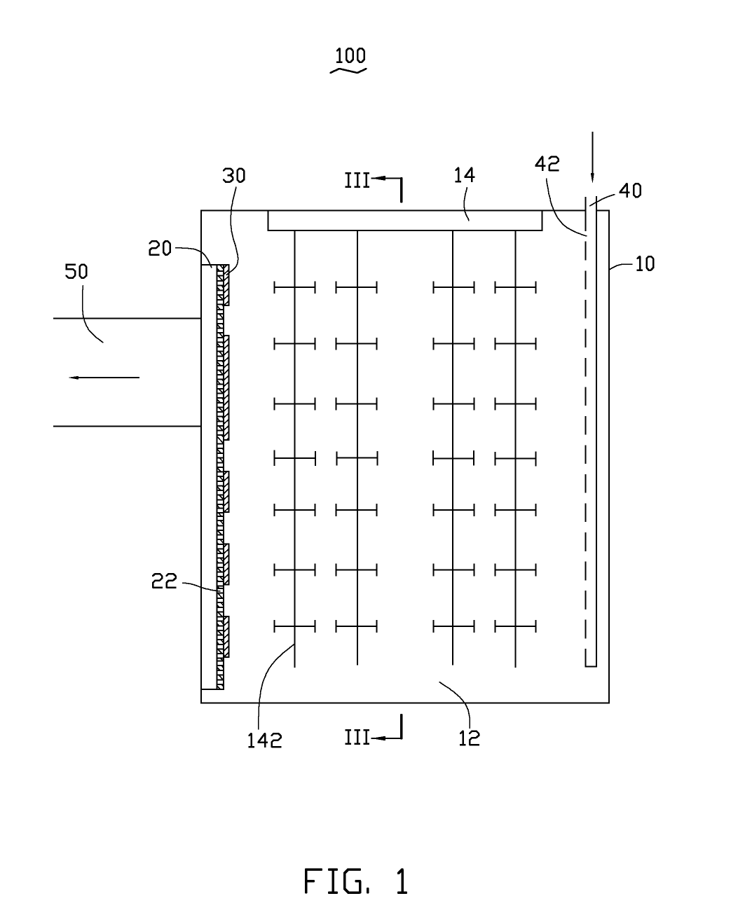

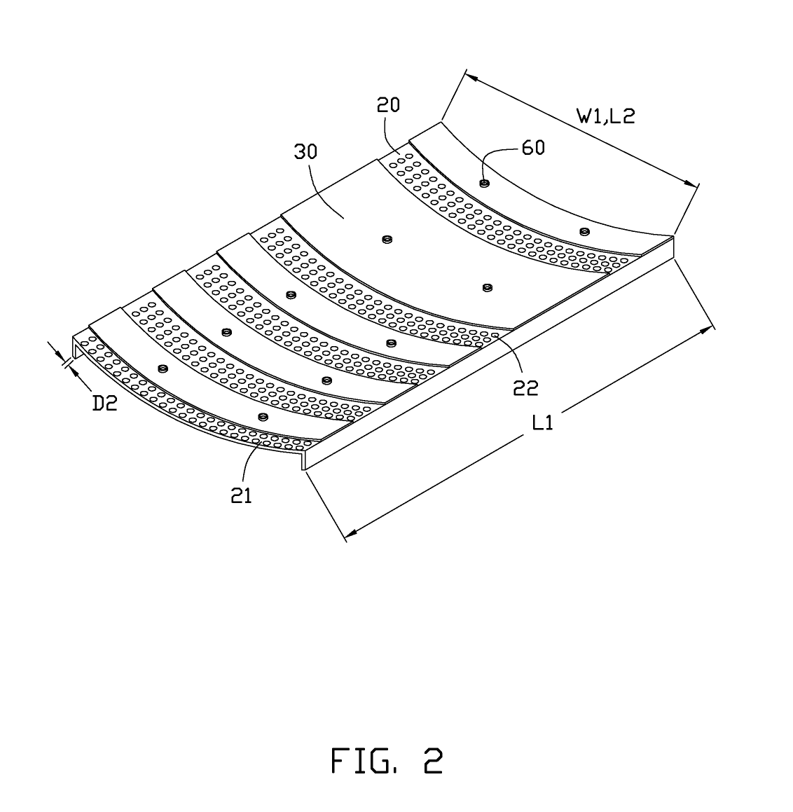

Referring to FIGS. 1 and 2, an exemplary embodiment of a flow divider system 100 used in a magnetron sputtering device is shown. The flow divider system 100 includes a gas box 10 and a shield 20 located in the gas box 10. The gas box 10 defines a chamber 12. The chamber 12 can be evacuated to form a vacuum space. In this exemplary embodiment, one side of the gas box 10 defines an outlet gate 50 connecting the chamber 12 to a vacuum pump of the magnetron sputtering device. The vacuum pump evacuates the chamber 12 through the outlet gate 50 forming a space having a desired degree of vacuum.

Referring to FIG. 1, the gas box 10 further includes a rotation board 14 rotatably retained in the chamber 12, a plurality of spaced hanging rods 142 fixed to the rotation board 14. The hanging rods 142 are used to hang workpieces to be coated.

Referring to FIG. 1, the gas box 10 further defines at least one inlet pipe 40 opposite to the outlet gate 50. Each inlet pipe 40 defines a plurality of openings 42 communicating with the chamber 12, so reacting gas, such as argon can be fed into the chamber 12 from the openings 42.

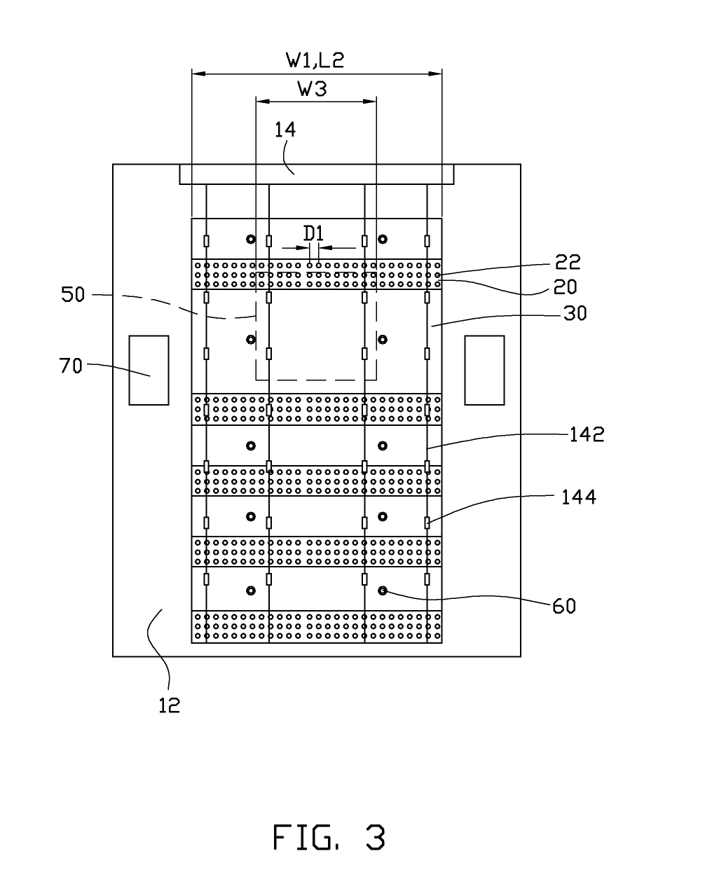

Referring to FIG. 3, the gas box 10 further includes at least one target 70. In this exemplary embodiment, the gas box 10 has two targets 70 located at different sides of the shield 20. The targets 70 may be made of titanium, chromium, zirconium, aluminum, or nickel.

Referring to FIGS. 2 and 3, the shield 20 is retained in the chamber 12 and shields the outlet gate 50. The shield 20 includes a main body 21. The main body 21 defines a plurality of holes 22. The gas in the chamber 12 passes through the openings 42 to the outlet gate 50. Each hole 22 has a diameter between about 0.5 millimeters and about 50 millimeters, and a distance D1 between centers of two adjacent holes 22 is between about 2 millimeters and about 50 millimeters. A width W1 of the shield 20 is wider than a width W3 of the outlet gate 50 by about 10 millimeters to about 300 millimeters. The main body 21 has a thickness D1 between about 0.5 millimeters and about 10 millimeters.

The shield 20 further includes a plurality of shield boards 30 fixed to the main body 21, and each shield board 30 has a length L2 equal to the width W1 of the main body 21. The shield boards 30 adjustably shield portions of the openings 42 to adjust the flow of the gas passing through the shield 20. In this exemplary embodiment, each shield board 30 is adjustably fixed to the main body 21 by a plurality of screws 60. To adjust the distances between the shield boards 30, the screws 60 are released, and then the shield boards 30 are moved on the main body 21 accordingly, and then the screws 60 are fastened again. As the shield boards 30 are adjusted, portions of the openings 42 being shielded are accordingly adjusted so the flow of the gas passing through the shield 20 is adjusted. In this exemplary embodiment, the distance between two adjacent shield boards 30 is between 10 millimeters and 400 millimeters.

In use, the workpieces are suspended from the hanging rods 142. The chamber 12 is evacuated through the outlet gate 50 by using the vacuum pump until a desired degree of vacuum formed in the chamber 12. The reacting gas (e., argon) is fed into the chamber 12 through the inlet pipe 40. The argon is ionized to argon ions to bombard the targets 70 so atoms are ejected from the targets 70 to coat the workpieces. If needed, the distances between the shield boards 30 can be adjusted to adjust the flow passing through the shield 20, and control utilization rate of the target 70.

It is to be understood, however, that even through numerous characteristics and advantages of the exemplary disclosure have been set forth in the foregoing description, together with details of the system and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A flow divider system, comprising:
a gas box defining a chamber and an outlet gate;
a shield located in the chamber and shielding the outlet gate, the shield comprising a main body, the main body defining a plurality of openings communicating the chamber with the outlet gate;
wherein the shielding can further comprises a plurality of shield boards adjustably retained to the main body, to adjustably shield portions of the openings.

2. The flow divider system as claimed in claim 1, wherein the chamber is evacuated to form a vacuum space.

3. The flow divider system as claimed in claim 1, wherein the outlet gate is defined in one side of the gas box.

4. The flow divider system as claimed in claim 1, wherein the gas box further comprises a rotation board rotatably retained in the chamber, and a plurality of spaced hanging rods fixed to the rotation board.

5. The flow divider system as claimed in claim 1, wherein the gas box further defines at least one inlet pipe opposite to the outlet gate.

6. The flow divider system as claimed in claim 5, wherein each inlet pipe defines a plurality of openings communicating with the chamber, a reacting gas is capable of being fed into the chamber from the openings.

7. The flow divider system as claimed in claim 1, wherein the gas box further includes at least one target located in the chamber.

8. The flow divider system as claimed in claim 1, wherein each hole has a diameter between about 0.5 millimeters and about 50 millimeters.

9. The flow divider system as claimed in claim 1, wherein a distance between centers of two adjacent holes is between about 2 millimeters and about 50 millimeters.

10. The flow divider system as claimed in claim 1, wherein a width of the shield is wider than that of the outlet gate between about 10 millimeters and about 300 millimeters.

11. The flow divider system as claimed in claim 1, wherein the main body has a thickness between about 0.5 millimeters and about 10 millimeters.

12. The flow divider system as claimed in claim 1, wherein each shield board has a length equal to the width of the main body.

13. The flow divider system as claimed in claim 1, wherein each shield board is adjustably retained to the main body by a plurality of screws.

14. A flow divider system, comprising:
a gas box defines a chamber and an outlet gate;
a shield located in the chamber and shielding the outlet gate, the shield including a main body, the main body defining a plurality of openings communicating the chamber with the outlet gate;
wherein the shielding can further comprises a plurality of shield boards adjustably retained to the main body, to adjust a flow of a gas passing through the shield.

15. The flow divider system as claimed in claim 14, wherein each hole has a hole opening size between about 0.5 millimeters and about 50 millimeters.

16. The flow divider system as claimed in claim 14, wherein a distance between centers of two near holes is between about 2 millimeters and about 50 millimeters.

17. The flow divider system as claimed in claim 14, wherein a width of the shield is wider than that of the outlet gate between about 10 millimeters and about 300 millimeters.

18. The flow divider system as claimed in claim 14, wherein the main body has a thickness between about 0.5 millimeters and about 10 millimeters.

19. The flow divider system as claimed in claim 14, wherein each shield board has a length equal to the width of the main body.

20. The flow divider system as claimed in claim 14, wherein each shield board is adjustably retained to the main body by a plurality of screws.
